(19) United States
(12) Patent Application Publication
(10) Pub. No.: US 2008/0074156 A1
(43) Pub. Date: Mar. 27, 2008

(54) CURRENT DRIVING TYPE LIGHT SOURCE DRIVING CIRCUIT

(76) Inventors: Ja-Won SEO, Suwon-si (KR); Seong-Min Seo, Yongin-si (KR)

Correspondence Address: CHA & REITER, LLC, 210 ROUTE 4 EAST STE 103, PARAMUS, NJ, 07652, US

(21) Appl. No.: 11/737,777

(22) Filed: Apr. 20, 2007

(30) Foreign Application Priority Data
Sep. 21, 2006 (KR) 2006-91715

(51) Int. Cl. H03B 1/00

(52) U.S. Cl. 327/108

(57) ABSTRACT

Disclosed is a current driving type light source driving circuit in a CMOS optical transmitter, the current driving type light source driving circuit including a constant current source adjusted by bias voltage to supply operating current, first and second circuit units operating based on a differential input signal received from the constant current source and an external source, a light source for converting the input signal into an output optical signal and a load device for uniformly adjusting a load of the light source.

### CLAIM OF PRIORITY

This application claims the benefit of the earlier filing date, pursuant to 35 USC 119, to that patent application entitled “Current Driving Type Light Source Driving Circuit” filed in the Korean Intellectual Property Office on Sep. 21, 2006 and assigned Serial No. 2006-91715, the contents of which are hereby incorporated by reference.

### BACKGROUND OF THE INVENTION

1. Field of the Invention

The present invention relates to a current driving type light source driving circuit, and more particularly to a current driving type light source driving circuit which can be maintained in a transmission-side by commonly using a differential signal in order to convert an electrical signal to be transmitted into an optical signal without an additional driving circuit.

2. Description of the Related Art

Generally, various data transmission schemes in one device or between two or more devices have been developed. One of these transmission schemes is differential data transmission in which a difference of voltage levels between two signal lines forms a transmission signal. For example, differential data transmission is typically used for data transmission speed greater than 100 Mbps in a long distance.

Such a driver circuit arranges a signal on a transmission line or medium, and drives the signal. A Low Voltage Differential Signaling (LVDS) driver is typically used for various applications including driving of a signal from a transmitter to a receiver. A typical LVDS driver permits high speed transmission, consumes low power, has low Electromagnetic Interference (EMI), and is low-priced.

The reason for differentiating a signal is that a signal having differential characteristics is transmitted, similarly to the principle of a differential amplifier, in order to restrict common mode noise, thereby removing the effect of noise commonly added/subtracted to/from two signals because a receiver determines signals based on only a difference between the two signals even when the two signals are interfered with by the common mode noise, wherein the common mode noise represents the bulk of noise components and simultaneously occurs with the same phase as the original signal.

Since such an LVDS transmission scheme corresponds to a recent tendency of a communication system in which transmission speed between internal chips or backplanes consecutively increases with the tendency of high speed and large capacity, and has been used for data transmission of an LCD driver requiring many transmission lines, it will be continuously developed.

FIG. 1 is a circuit diagram of a conventional LVDS driver.

As illustrated in FIG. 1, in the conventional LVDS driver 100, a voltage difference between output signals OUT+ and OUT− forms one pair of differential signals. The differential signals denote two signals in which current waveforms have a phase difference of 180°.

The LVDS driver 100 includes a first direct current constant current source 11 coupled to a power source VDD, two PMOS transistors P1 and P2 (which represent a differential pair), two NMOS transistors N1 and N2 (which also represent a differential pair), a common node COM, and a second direct current constant current source 12 coupled to a ground. The four differential pair transistors P1, P2, N1 and N2 are controlled by input voltage signals D+ and D−, and direct current passing through a load resistor R_{LOAD} as indicated by arrows A and B. The input voltage signals D+ and D− are typically rail-to-rail voltage swing.

Hereinafter, the operation of the LVDS driver 100 will be described. Two of the four transistors P1, P2, N1 and N2 are simultaneously turned on, and adjust current from the current sources 11 and 12 so as to generate voltage applied to the load resistor R_{LOAD}. In order to cause current to pass through the load resistor R_{LOAD} in a direction indicated by arrow A, the input signal D+ is switched into a high state to turn on the transistor N1 and to turn off the transistor P1, and simultaneously the input signal D− is switched into a low state to turn on the transistor P2 and to turn off the transistor N2.

However, in order to cause current to pass through the load resistor R_{LOAD} in a direction indicated by arrow B, the input signal D− is switched into a high state to turn on the transistor N2 and to turn off the transistor P2, and simultaneously the input signal D+ is switched into a low state to turn on the transistor P1 and to turn off the transistor N1. In this way, full differential output voltage swing can be obtained.

The conventional LVDS driver 100 normally operates as long as output voltage swing exists within the allowable common mode voltage range (generally, several Volts).

The LVDS driver 100 can provide power source supply rejection of good quality. Common mode voltage VCM is set by an external bias voltage through a resistor R1. It is ideal that common mode voltage is maintained within a predetermined level or range. In many cases, common mode voltage of 1.25V is used.

The LVDS driver 100 has disadvantages in that it requires a higher power source supply level in order to cause transistors to be properly biased for a predetermined time period. Transistors forming the current source 11 and 12 must have sufficient voltage in order to maintain a saturated state. The differential pairs P1, P2, N1 and N2 have minimum voltage drop relating to output current and channel resistance.

Accordingly, all of the transistors must be properly biased for a predetermined time period within the output signal swing range. In order to cause the driver to operate in all processes, several margins, i.e. voltage and temperature (PVT), must be added. These biasing requirements are applied as shown to CMOS circuits or bipolar junction transistors. For example, a typical LVDS push-pull driver requires a voltage supply of about 0.5V in order to properly maintain bias at a standard common mode level of about 1.25V. Therefore, a supply voltage level requested by the conventional LVDS driver limits the development of a low power application apparatus and device to which power source lower than 2.5V is applied.

FIG. 2 is a diagram illustrating the construction of a system using a conventional LVDS driver.

As illustrated in FIG. 2, a general transmitter using the LVDS driver 100 switches a current source to four switches in an output buffer-side (not shown), and a receiver detects and amplifies a difference of voltage applied to both sides of a resistor of 100Ω (not shown).

In such a conventional LVDS driver 100, one transmitter differentiates one signal to transmit the differentiated signal to two transmission lines, and one receiver receives one signal. Therefore, two transmission lines are necessary for transmitting one signal. That is, in order to transmit one signal, since the original signal and the inverted signal are necessarily used, two transmission lines and two input/output pins are necessary. As a result, miniaturization is difficult, and power consumption is relatively high.

### SUMMARY OF THE INVENTION

Accordingly, the present invention has been made to provide a light source driving circuit which (1) can be maintained in a transmission-side by commonly using a differential signal in order to convert an electrical signal to be transmitted into an optical signal without an additional driving circuit and to transmit the optical signal, (2) can reduce an occupation area in the transmission-side of an existing electrical interface, and (3) can decrease power consumption by using relatively low power, in an Ethernet or optic fiber channel environment.

In accordance with one aspect of the present invention, there is provided a light source driving circuit in a CMOS optical transmitter, the current driving type light source driving circuit including a constant current source adjusted by bias voltage to supply operating current, first and second circuit units operating based on a differential input signal received from the constant current source and an external source, a light source for converting the input signal into an output optical signal and a load device for uniformly adjusting a load of the light source.

### BRIEF DESCRIPTION OF THE DRAWINGS

The above and other objects, features and advantages of the present invention will be more apparent from the following detailed description taken in conjunction with the accompanying drawings, in which:

FIG. 1 is a circuit diagram of a conventional LVDS driver;

FIG. 2 is a diagram illustrating the construction of a system using a conventional LVDS driver;

FIG. 3 is a circuit diagram of a current driving type light source driving circuit according to an exemplary embodiment of the present invention;

FIG. 4 is a graph illustrating a light intensity-current/voltage LI-IV characteristic for a VCSEL with a short wavelength according to an exemplary embodiment of the present invention; and

FIG. 5 is a diagram illustrating the construction of a system using the current driving type light source driving circuit according to an exemplary embodiment of the present invention.

### DETAILED DESCRIPTION OF THE INVENTION

An exemplary embodiment of the present invention will be described in detail herein below with reference to the accompanying drawings. In the following description, a detailed description of known functions and configurations incorporated herein will be omitted when it may obscure the subject matter of the present invention.

The current driving type light source driving circuit of the present invention operates at a supply voltage lower than 2.5V at which the conventional LVDS driver operates. The current driving type light source of the present invention driving circuit operates at a supply voltage in the range of 1.5 to 1.8V.

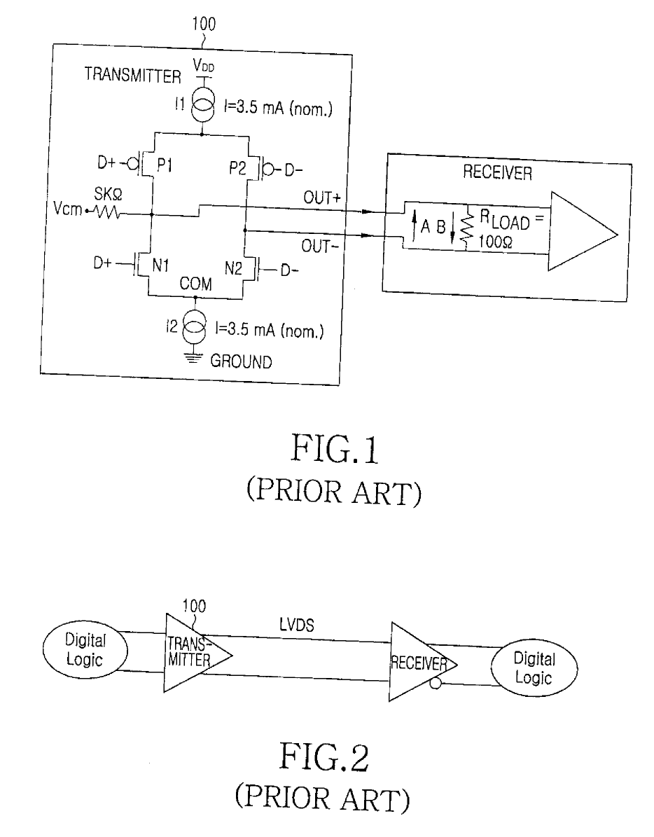

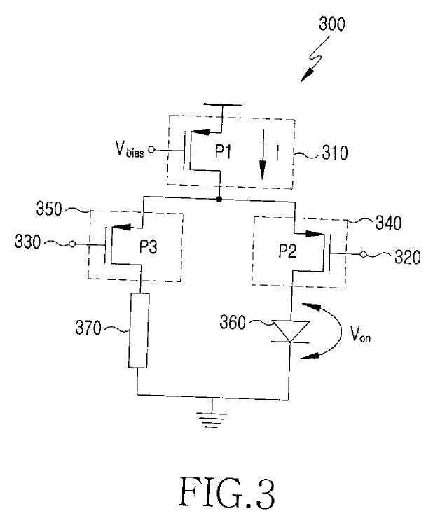

Similar to the conventional LVDS driver illustrated in FIG. 1 in the aspect of the invention shown in FIG. 3, transistors P1, N1, P2 and N2 function as current adjustment switches operating current through a load resistor R_{LOAD} based on the states of CMOS input signals D+ and D−. However, the present invention employs a single constant current source instead of two current sources. In addition, it is not necessary for any external voltage bias to set the common mode voltage level of a driver.

FIG. 3 is a circuit diagram of a current driving type light source driving circuit according to one embodiment of the present invention,

As illustrated in FIG. 3, the light source driving circuit 300 includes a constant current source 310 of a PMOS transistor P1 functioning as a current source for generating current I through adjustment by bias voltage V_{bias}, and a first circuit unit 340 and a second circuit unit 350, respectively, operating based on CMOS input signals D+ and D− received from input terminals 320 and 330.

Each of the input terminals 320 and 330 receives both a bias factor for allowing a Vertical Cavity Surface Emitting Laser (VCSEL) 360 to be maintained at more than a laser threshold voltage thereof, and the CMOS input signals D+ and D− providing signals to be transmitted by the VCSEL 360.

The input terminal 320 receives one input signal, and the other input terminal 330 receives a copied inversion of the input signal. The output lead of the first circuit unit 340 is connected to the VCSEL 360, but the second circuit unit 350 is connected to a load device 370 selected in order to uniformly adjust the load of the VCSEL 360. The VCSEL 360 and the load device 370 are grounded as illustrated in FIG. 3.

The two input terminals 320 and 330 include PMOS transistors P2 and P3, respectively, and are controlled by the CMOS input signals D+ and D− and direct current passing through the load device 370. The CMOS input signals D+ and D− are typically rail-to-rail voltage swing.

The current I, from the constant current source 310, is adjusted so that one of the two PMOS transistors P1 and P2 is turned-on so as to generate voltage. That is, in order to cause current to pass through the VCSEL 360, the input signal D− is switched into a high state to turn on the transistor P2, and simultaneously the input signal D+ is switched into a low state to turn off the transistor P3.

However, in order to cause current to pass through the load device 370, the input signal D+ is switched into a high state to turn on the transistor P3, and simultaneously the input signal D− is switched into a low state to turn off the transistor P2. In this way, full differential output voltage swing can be obtained. The above embodiment employs the PMOS transistors 340 and 350. However, it should be noted that it is possible to employ other types of transistors or other equivalents using different combinations of transistors without departing from the scope and spirit of the present invention.

The load device 370 has an impedance nearly equal to the low frequency impedance of the VCSEL 360. When impedances shown in the circuit units 340 and 350 are not matched, an error occurs in waveform transmitted to the VCSEL 360. In order to provide clear waveform to the VCSEL 360, the circuit units 340 and 350 are matched.

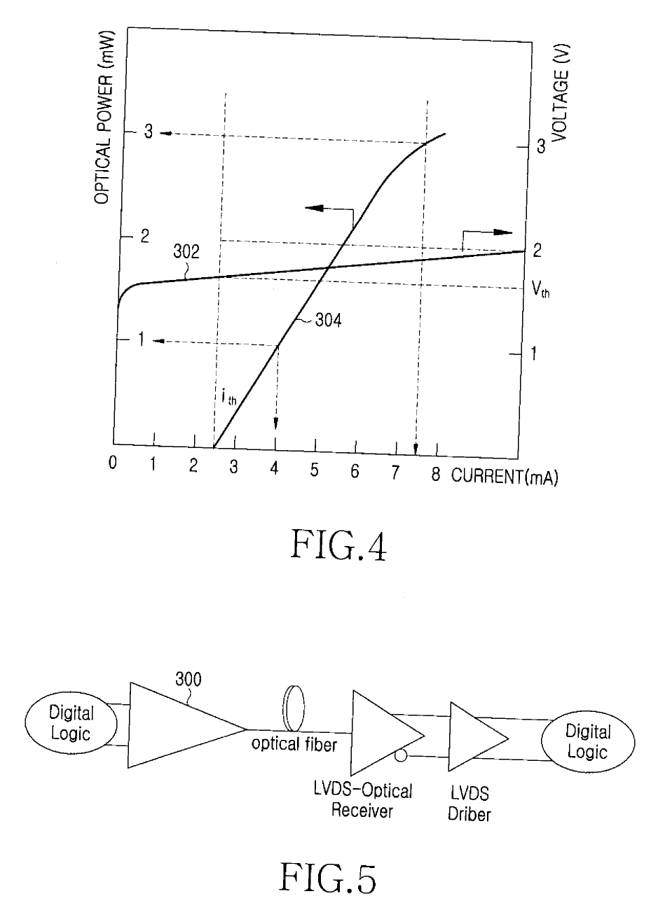

FIG. 4 is a graph illustrating a light intensity-current/voltage LI-IV characteristic for a VCSEL with a short wavelength according to the described embodiment of the present invention.

FIG. 4 illustrates a light power-current/voltage LI-IV characteristic for the VCSEL 360 with a short wavelength of 350 nm, which can operate at more than 10 Gbits per second by the current driving type light source driving circuit 300 according to the illustrated embodiment of the present invention. The VCSEL 360 has a characteristic of current-voltage I/V shown in a curve 302 similar to that of a certain typical diode.

The light emission characteristic of the VCSEL 360 is indicated by a light power-current curve 304. The VCSEL 360 starts to current saturate at about or slightly higher than 1.6V, and starts to emit laser light at 1.7V, i.e. threshold voltage Vₜₕ and 1 mA. However, the VCSEL 360 reaches driving voltage of 1.8 to 2.0V at a device current of 4 to 8 mA, and then does not emit laser at any recognizable level before reaching 3 to 3.5 mW of power approximating a maximum power of the VCSEL 360 for Continuous Wave (CW) emission.

In the light source driving circuit 300 of the present invention, one side of the VCSEL 360 is driven in high performance for reaching driving voltage of 1.8 to 2.0V even at a data rate in which voltage in both sides of the VCSEL 360 is high. The performance of the VCSEL 360 is improved through the current driving type light source driving circuit operating at total diode voltage of 1.8 to 2.0V together with biasing voltage at Vₜₕ. A forward-biased semiconductor junction device such as the VCSEL 360 quickly responds to changes in voltage when it is turned off or is backward-biased. Performance difference is known as a turn-on type or a turn-on delay. For example, a very important turn-on delay may be avoided by biasing the VCSEL 360 at 1.7V or 2 mA. Then, the biased VCSEL 360 is switched-in or out at a much higher switching rate. Accordingly, the VCSEL 360 is preferably turned on or off by a serial transmission circuit such as the current driving type light source driving circuit 300.

As described above, the emission point of the VCSEL 360 is formed so that the VCSEL 360 does not operate at a high level for allowing the VCSEL 360 to be in an emission state, i.e., the supply voltage V_{bias} of the current driving type light source driving circuit 300 is smaller than Vₜₕ. Instead of causing the VCSEL 360 to operate at the emission point or below the emission point by the bias voltage, the current driving type light source driving circuit 300 provides additional operation so that the VCSEL 360 is sufficiently emitting. The VCSEL 360 shows low voltage swing in a differential operation mode formed between the output of the two circuit units 340 and 350 in response to rapid changes in signal current.

At least one load device 370 prevents the VCSEL 360 from being turned on when the current driving type light source driving circuit 300 does not operate. Preferably, the load device 370, which may be reactive or resistant, or reactive and resistant, is a reactive device with a high Q, i.e. a device with minimum resistance. Accordingly, the load device 370 may be an inductor or a capacitor with a high Q, or a resistor with low resistance. If the current driving type light source driving circuit 300 selectively operates the VCSEL 360 for emission, the load device 370 causes current through the VCSEL, 360 to be maintained at emission current or below the emission current. The current approximates to low frequency impedance of the VCSEL 360 according to the output of the VCSEL 360.

FIG. 5 is a diagram illustrating the construction of a system using the current driving type light source driving circuit according to the preferred embodiment of the present invention.

As illustrated in FIG. 5, the current driving type light source driving circuit 300 can (1) be maintained in a transmission-side by commonly using a differential signal in order to convert an electrical signal to be transmitted into an optical signal and to transmit the optical signal, (2) decrease power consumption by using relatively low power in a serial transmission circuit instead of parallel transmission substituting for an existing electrical interface, and (3) reduce an occupation area in the transmission-side, in an Ethernet or optic fiber channel environment.

According to the present invention as described above, a light source driving circuit can be maintained in a transmission-side by commonly using a differential signal in order to convert an electrical signal to be transmitted into an optical signal without an additional driving circuit and to transmit the optical signal, can decrease power consumption by using relatively low power in a serial transmission circuit instead of parallel transmission substituting for an existing electrical interface, and can reduce an occupation area in the transmission-side, in an Ethernet or optic fiber channel environment.

Although one embodiment of the present invention has been described in detail for illustrative purposes, those skilled in the art will appreciate that various modifications, additions and substitutions are possible, without departing from the scope and spirit of the present invention as disclosed in the accompanying claims, including the full scope of equivalents thereof.

What is claimed is:

1. A current driving type light source driving circuit in a CMOS optical transmitter, the current driving type light source driving circuit comprising:
a constant current source adjusted by a bias voltage to supply an operating current;
first and second circuit units operating based on a differential input signal received from the constant current source and an external source;
a light source for converting the input signal into an output optical signal; and
a load device for uniformly adjusting a load of the light source.

2. The current driving type light source driving circuit as claimed in claim 1, wherein the constant current source includes a PMOS transistor and functions as a current source.

3. The current driving type light source driving circuit as claimed in claim 1, wherein the circuit unit includes a PMOS transistor and performs rail-to-rail voltage swing based on the differential input signal.

4. The current driving type light source driving circuit as claimed in claim 1, wherein the light source includes a Vertical Cavity Surface Emitting Laser (VCSEL) connected to output of the first circuit unit and performs swing at low voltage of differential output.

5. The current driving type light source driving circuit as claimed in claim 1, wherein the load device is connected to an output of the second circuit unit and has impedance equal to a low frequency impedance of the light source.

6. The current driving type light source driving circuit as claimed in claim 5, wherein the load device causes the first circuit unit to be matched with the second circuit unit in order to prevent an error from occurring in a waveform transmitted to the light source.

7. The current driving type light source driving circuit as claimed in claim 1, further comprising:
a serial transmission circuit operating based on the differential input signal.

8. A the current driving type light source driving circuit comprising:
a PMOS transistor constant current source adjusted by a bias voltage to supply an operating current;
first and second circuit units operating based on a differential input signal received from the constant current source and an external source;
a light source for converting the input signal into an output optical signal; and
a load device for uniformly adjusting a load of the light source.

9. The current driving type light source driving circuit as claimed in claim 8, wherein the PMOS transistor performs rail-to-rail voltage swing based on the differential input signal.

10. The current driving type light source driving circuit as claimed in claim 8, wherein the light source includes a Vertical Cavity Surface Emitting Laser (VCSEL) connected to an output of the first circuit unit.

11. The current driving type light source driving circuit as claimed in claim 8, wherein the load device is connected to an output of the second circuit unit and has impedance equal to a low frequency impedance of the light source.

12. The current driving type light source driving circuit as claimed in claim 8, wherein the load device causes the first circuit unit to be matched with the second circuit unit.

13. The current driving type light source driving circuit as claimed in claim 8, further comprising:
a serial transmission circuit operating based on the differential input signal.

14. A the current driving type light source driving circuit comprising:
a PMOS transistor constant current source adjusted by a bias voltage to supply an operating current;
first and second circuit units operating based on a differential input signal received from the constant current source and an external source;
a light source for converting the input signal into an output optical signal, said light source includes a Vertical Cavity Surface Emitting Laser (VCSEL) connected to an output of the first circuit unit;
a load device for uniformly adjusting a load of the light source, wherein the load device is connected to an output of the second circuit unit and has impedance equal to a low frequency impedance of the light source; and
a serial transmission circuit operating based on the differential input signal.

15. The current driving type light source driving circuit as claimed in claim 14, wherein the PMOS transistor performs rail-to-rail voltage swing based on the differential input signal.

16. The current driving type light source driving circuit as claimed in claim 14, wherein the load device causes the first circuit unit to be matched with the second circuit unit.
